(19) United States
(12) Patent Application Publication
(10) Pub. No.: US 2009/0051252 A1
(43) Pub. Date: Feb. 26, 2009

(54) Piezoelectric Resonator Plate And Piezolectric Resonator Device

(76) Inventor: Takashi Shirai, Hyogo (JP)

Correspondence Address: WENDEROTH, LIND & PONACK, L.L.P., 2033 K STREET N. W., SUITE 800, WASHINGTON, DC, 20006-1021, US

(21) Appl. No.: 11/921,639

(22) PCT Filed: Apr. 21, 2006
(86) PCT No.: PCT/JP2006/308444

§ 371 Date: Dec. 6, 2007

(30) Foreign Application Priority Data
Jun. 30, 2005 (JP) 2005-190822

(51) Int. Cl. H01L 41/02

(52) U.S. Cl. 310/348

(57) ABSTRACT

A piezoelectric resonator plate includes a base portion and a vibrating portion having a plurality of leg portions. Each of the leg portions is provided with an excitation electrode and a lead electrode. At least two conductive bonding member forming regions for bonding a part of the lead electrode to an external electrode via a conductive bonding member are defined in the base portion. The base portion is formed wider than the vibrating portion and has a base portion central region and base portion wider regions, the base portion central region having the same width as the vibrating portion, the vibrating portion extending from the base portion central region, and the base portion wider regions extending beyond lateral edges of the vibrating portion, the conductive bonding member forming regions being defined in the base portion wider regions. Elongated thin-walled portions starting at boundary corner portions of the base portion between the base portion central region and the base portion wider regions are formed in this base portion. Alternatively, elongated thin-walled portions starting at corner portions on a side of the base portion wider regions from which the leg portions extend are formed in the base portion.

### TECHNICAL FIELD

The present invention relates to a piezoelectric resonator plate and a piezoelectric resonator device, more particularly to a structure of a piezoelectric resonator plate.

### BACKGROUND ART

Piezoelectric resonator devices include a tuning fork crystal resonator using a tuning fork crystal resonator plate composed of a base portion and a vibrating portion having two leg portions protruding from this base portion (see Patent Document 1, for example). This tuning fork crystal resonator is used in electronic apparatuses, portable terminals, and the like to provide a precise clock frequency.

A tuning fork crystal resonator as described above has a housing composed of a base and a lid, and within this housing, a tuning fork crystal resonator plate that is bonded to and held on the base via a conductive bonding member is hermetically enclosed. As the conductive bonding member, for example, a conductive adhesive is used. By bonding the base portion of the tuning fork crystal resonator plate and the base together using the conductive adhesive, electrical conduction is established between an excitation electrode provided in the tuning fork crystal resonator plate and an electrode pad provided in the base.

Patent Document 1 describes a configuration in which a base portion of a tuning fork crystal resonator plate is provided with a cut groove. The patent document discloses that this configuration alleviates leakage of vibration in leg portions to the base portion side and lowers the CI value (crystal impedance) by enhancing an effect of confining vibrational energy. Patent Document 1: JP 2004-260718A

### DISCLOSURE OF INVENTION

### Problem to be Solved by the Invention

However, in the tuning fork crystal resonator described in Patent Document 1, as the size of tuning fork crystal resonator plates is further reduced, there is a trend toward a further reduction of the base portion region. Specifically, when the base portion region is further reduced (especially the length of the base portion is shortened), not only a good effect of confining vibrational energy can no longer be expected, but also an effective bonding region for the conductive bonding member can no longer be secured in the base portion, so that there are problems such as that the bond strength to an object to be bonded, e.g., the base of the tuning fork crystal resonator, is decreased.

Thus, in order to solve the foregoing problems, it is an object of the present invention to provide a piezoelectric resonator plate and a piezoelectric resonator device which offer a higher degree of reliability and with which the size of piezoelectric resonator plates can be reduced without decreasing the bond strength of the piezoelectric resonator plates and the CI value (crystal impedance) can be lowered by enhancing the effect of confining vibrational energy.

### Means for Solving Problem

In order to achieve the object, a piezoelectric resonator plate according to the present invention includes a base portion and a vibrating portion having a plurality of leg portions protruding from the base portion. Each of the leg portions is provided with an excitation electrode having a different potential and a lead electrode connected to the excitation electrode so as to electrically connect the excitation electrode to an external electrode. At least two conductive bonding member forming regions for bonding a part of the lead electrode to the external electrode via a conductive bonding member are defined in the base portion. The base portion is formed wider than the vibrating portion and has a base portion central region and base portion wider regions, the base portion central region having the same width as the vibrating portion, the vibrating portion extending from the base portion central region, and the base portion wider regions extending beyond lateral edges of the vibrating portion, the conductive bonding member forming regions being defined in the base portion wider regions. Elongated thin-walled portions starting at boundary corner portions of the base portion between the base portion central region and the base portion wider regions are formed in the base portion.

According to the present invention, the base portion is formed wider than the vibrating portion and has the base portion central region and the base portion wider regions, and the thin-walled portions are formed in the base portion, so that transmission of vibrational energy generated in the vibrating portion is weakened by the base portion wider regions and efficiently blocked by the thin-walled portions starting at the boundary corner portions between the base portion central region and the base portion wider regions. Accordingly, it is possible to reduce leakage of vibration from the vibrating portion to each of the conductive bonding member forming regions while realizing a reduction in the size of the base portion. Moreover, since the elongated thin-walled portions starting at the boundary corner portions between the base portion central region and the base portion wider regions are formed, it is possible to effectively dispose the conductive bonding member forming regions in the base portion wider regions without increasing the length of the base portion of the piezoelectric resonator plate, and also the bond strength of the piezoelectric resonator plate is not decreased. In addition, since the thin-walled portions are elongated, the rigidity of the base portion of the piezoelectric resonator plate is not decreased, and breakage or the like of the piezoelectric resonator plate no longer occurs.

Moreover, a piezoelectric resonator plate according to the present invention includes a base portion and a vibrating portion having a plurality of leg portions protruding from the base portion. Each of the leg portions is provided with an excitation electrode having a different potential and a lead electrode connected to the excitation electrode so as to electrically connect the excitation electrode to an external electrode. At least two conductive bonding member forming regions for bonding a part of the lead electrode to the external electrode via a conductive bonding member are defined in the base portion. The base portion is formed wider than the vibrating portion and has a base portion central region and base portion wider regions, the base portion central region having the same width as the vibrating portion, the vibrating portion extending from the base portion central region, and the base portion wider regions extending beyond lateral edges of the vibrating portion, the conductive bonding member forming regions being defined in the base portion wider regions. Elongated thin-walled portions starting at corner portions on a side of the base portion wider regions from which the leg portions extend are formed in the base portion.

According to the present invention, the base portion is formed wider than the vibrating portion and has the base portion central region and the base portion wider regions, and the thin-walled portions are formed in the base portion, so that transmission of vibrational energy generated in the vibrating portion is weakened by the base portion wider regions and efficiently blocked at a position closest to the vibrating portion by the thin-walled portions starting at the corner portions that are located on the side of the base portion wider regions from which the leg portions extend. Accordingly, it is possible to suppress diffusion of leakage of vibration to the base portion and reduce the leakage of vibration from the vibrating portion to each of the conductive bonding member forming regions while realizing a reduction in the size of the base portion. Moreover, since the conductive bonding member forming regions can be disposed close to the vibrating portion, it is possible to realize a further reduction in the size of the base portion by suppressing an increase in the length of the base portion. The conductive bonding member forming regions can be effectively disposed in the base portion wider regions without increasing the length of the base portion of the piezoelectric resonator plate, and also the bond strength of the piezoelectric resonator plate is not decreased. In addition, since the thin-walled portions are elongated, the rigidity of the base portion of the piezoelectric resonator plate is not decreased, and breakage or the like of the piezoelectric resonator plate no longer occurs.

In the above-described configuration, terminal end portions of the thin-walled portions may be located farther inside the base portion than the conductive bonding member forming regions.

In this case, in addition to the above-described functions and effects, since the terminal end portions of the thin-walled portions are located farther inside the base portion than the conductive bonding member forming regions, it is possible to inhibit linear connection of each of the conductive bonding member forming regions and the vibrating portion, and thus the effect of blocking the transmission of vibrational energy generated in the vibrating portion is further enhanced. Accordingly, it is possible to still further reduce leakage of vibration from the vibrating portion to each of the conductive bonding member forming regions while realizing a reduction in the size of the base portion.

In the above-described configuration, the conductive bonding member may be a conductive adhesive.

In the above-described configuration, the conductive bonding member may be a conductive bump. In this case, in addition to the above-described functions and effects, the conductive bonding member forming regions can be made smaller than in the case of the conductive adhesive, which can contribute to a further reduction in the size of the piezoelectric resonator plate. Moreover, according to the present invention, also an impact during bonding of the conductive bump is absorbed by the elongated thin-walled portions, so that cracking or chipping of the piezoelectric resonator plate can be avoided, which is preferable.

In the above-described configuration, the leg portion may have a groove in a major surface thereof, and a part of the excitation electrode may be formed within the groove.

In this case, in addition to the above-described functions an effects, since the leg portion has the groove in a major surface thereof and a part of the excitation electrode is formed within the groove, vibration loss in the leg portions is suppressed even when the size of the piezoelectric resonator plate is reduced, and the CI value (crystal impedance) can be kept low.

Moreover, in order to achieve the object, a piezoelectric resonator device according to the present invention is characterized in that a base and a lid are bonded together to form a housing inside of which is hermetically enclosed, the base within the housing is provided with an electrode pad constituting the external electrode, and the conductive bonding member forming region of the piezoelectric resonator plate according to the present invention is bonded to the electrode pad via a bonding member.

According to the present invention, a piezoelectric resonator device having functions and effects similar to those of the above-described piezoelectric resonator plate according to the present invention can be provided. Moreover, when stress due to an impact from the outside or an influence from the outside occurs and results in distortion stress from the housing to the vibrating portion of the piezoelectric resonator plate, the elongated thin-walled portions can prevent the stress that has occurred from being transmitted to the vibrating portion, so that it is possible to effectively prevent a change in the CI value or a change in the frequency due to the occurrence of stress from the outside.

### EFFECTS OF THE INVENTION

According to the present invention, it is possible to provide a piezoelectric resonator plate and a piezoelectric resonator device which offer a higher degree of reliability and with which the size of piezoelectric resonator plates can be reduced without decreasing the bond strength of the piezoelectric resonator plates and the CI value (crystal impedance) can be lowered by enhancing the effect of confining vibrational energy.

### BRIEF DESCRIPTION OF DRAWINGS

FIG. 1 is a schematic exploded perspective view illustrating a base and a tuning fork crystal resonator plate constituting a tuning fork crystal resonator according to a first embodiment of the present invention.

FIG. 2 is a schematic cross-sectional view of the tuning fork crystal resonator according to the first embodiment, taken along line A-A of FIG. 1 in the direction of the arrow.

FIG. 3 is a schematic cross-sectional view of a tuning fork crystal resonator according to a second embodiment of the present invention.

FIGS. 4(a) to 4(d) are schematic perspective views of tuning fork crystal resonator plates according to other variant examples.

FIGS. 5(a) to 5(c) are schematic perspective views of tuning fork crystal resonator plates according to other variant examples.

### DESCRIPTION OF REFERENCE NUMERALS

1 tuning fork crystal resonator

11 inner portion of a housing

2 tuning fork crystal resonator plate

3 base

35, 36 electrode pad

4 lid

5 conductive bonding member

6 substrate

65a, 65b lead electrode

7a, 7b thin-walled portion

### BEST MODE FOR CARRYING OUT THE INVENTION

Hereinafter, a first embodiment of the present invention will be described with reference to the accompanying drawings. It should be noted that in embodiments described below, the present invention is applied to a tuning fork crystal resonator as a piezoelectric resonator device.

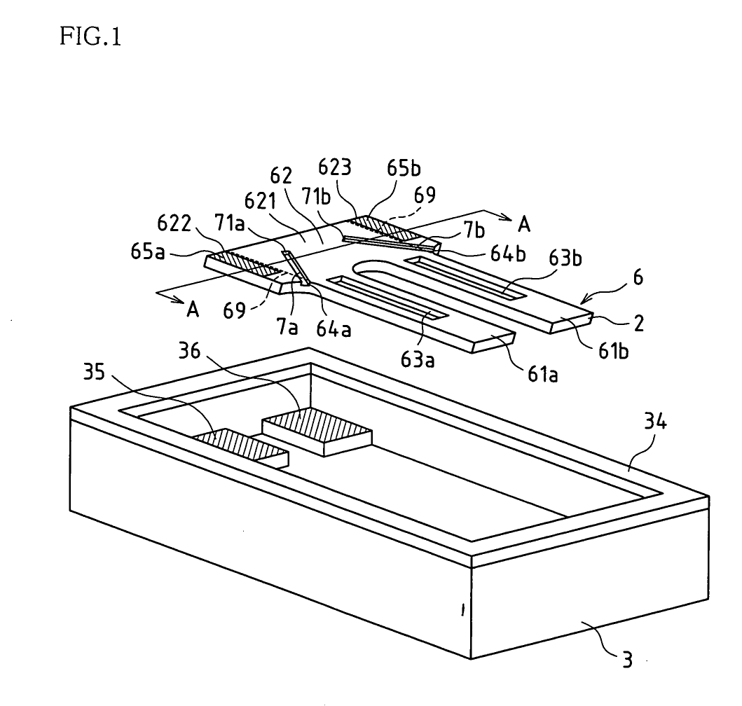

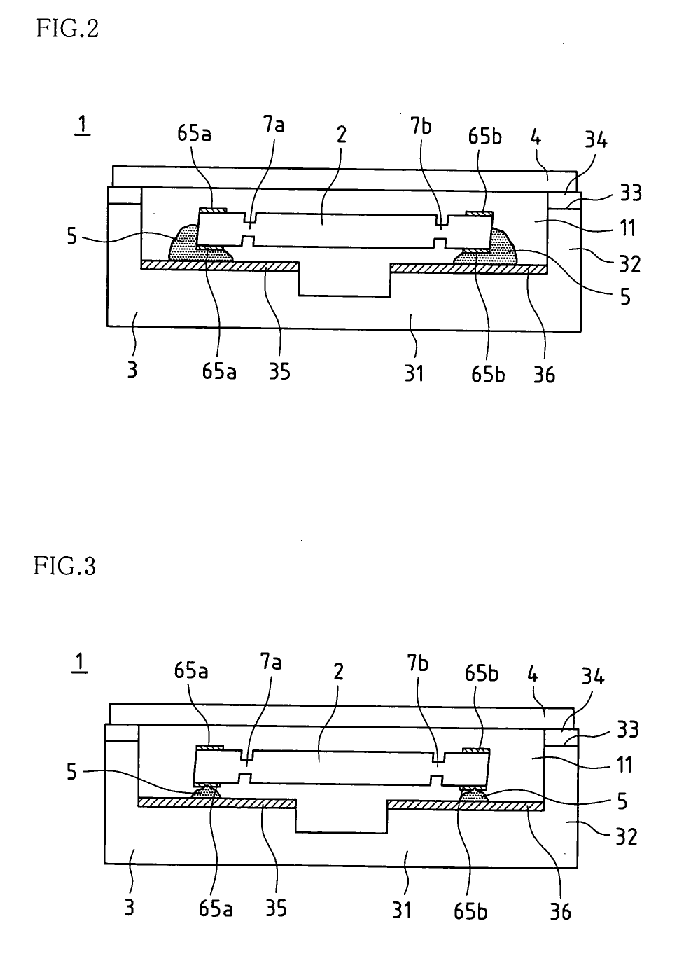

As shown in FIGS. 1 and 2, a tuning fork crystal resonator 1 according to this embodiment includes a tuning fork crystal resonator plate 2 (a piezoelectric resonator plate as used herein), a base 3 for holding the tuning fork crystal resonator plate 2, and a lid 4 for hermetically enclosing the tuning fork crystal resonator plate 2 held on the base 3. In the tuning fork crystal resonator 1, as shown in FIG. 2, the base 3 and the lid 4 are bonded together to form a housing, the tuning fork crystal resonator plate 2 is bonded onto the base 3 in a housing inner portion 11, and the housing inner portion 11 is hermetically enclosed. In this case, as shown in FIG. 2, the base 3 and the tuning fork crystal resonator plate 2 are bonded together using a conductive bonding member 5.

Next, each element of this tuning fork crystal resonator 1 will be described. The base 3 is made of, for example, a ceramic material, and as shown in FIG. 1, is formed in the shape of a box composed of a bottom surface portion 31 and a wall portion 32 extending upward from the bottom surface portion 31. The wall portion 32 is provided along the periphery of a surface of the bottom surface portion 31. A metallized layer 34 for bonding to the lid 4 is provided on an upper end portion 33 of the wall portion 32 of the base 3. Moreover, electrode pads 35 and 36 electrically connected to lead electrodes 65a and 65b described later of the tuning fork crystal resonator plate 2 are provided at both end portions of one side of the bottom surface portion 31 in an inner portion (see the housing inner portion 11) of the base 3 that is defined by the bottom surface portion 31 and the wall portion 32. These electrode pads 35 and 36 are electrically connected to respective terminal electrodes (not shown) formed on a rear surface of the base 3, and are connected via these terminal electrodes to external apparatuses. The electrode pads 35 and 36 and the terminal electrodes are formed by printing a metallization material, such as tungsten, molybdenum, or the like, before baking these parts together with the base 3, and for example, nickel plating and gold plating are provided thereon.

The lid 4 is, as shown in FIG. 2, made of a metallic material and formed in the shape of a rectangular solid (single board) having a rectangular shape when viewed from the top. A wax material that is not shown is formed on a lower surface of this lid 4, and is bonded to the base 3 by a method such as seam welding or beam welding, and thus, a housing of the tuning fork crystal resonator 1 is composed of the lid 4 and the base 3. The housing inner portion 11 as used in this embodiment refers to a portion hermetically enclosed by the lid 4 and the base 3. Alternatively, the lid 4 may be made of a ceramic material, and hermetic enclosure may be achieved via a glass material.

As the material for the conductive bonding member 5, for example, a silicone conductive adhesive containing a plurality of silver fillers is employed. By curing the conductive adhesive, the plurality of silver fillers is combined together into a conductive substance. Although silicone containing a plurality of silver fillers is employed, the present invention is not limited to this.

The tuning fork crystal resonator plate 2 is, as shown in FIGS. 1 and 2, formed by etching a substrate 6 made of a piece of crystal crystal, which is an anisotropic material. The substrate 6 includes a vibrating portion composed of two leg portions 61a and 61b (a first leg portion and a second leg portion) and a base portion 62, the two leg portions 61a and 61b extend from the base portion 62, and the base portion 62 is formed wider than the vibrating portion (leg portions 61a and 61b). Grooves 63a and 63b are formed in both major surfaces (front major surface and rear major surface) of the two leg portions 61a and 61b. The grooves 63a and 63b as used in this example have a concave cross section as shown in FIG. 1. However, the present invention is not limited to this, and the grooves 63a and 63b may be through holes, or may be depressions.

Two excitation electrodes (a first excitation electrode and a second excitation electrode) that are not shown and that have different potentials, and the lead electrodes 65a and 65b (conductive bonding member forming regions as used herein) led from the excitation electrodes so as to electrically connect the excitation electrodes to the electrode pads 35 and 36 (external electrodes as used herein) are provided on the surface of the tuning fork crystal resonator plate 2. In FIGS. 1 and 2, the lead electrodes 65a and 65b are shown partially, and the lead electrodes 65a and 65b as used in this embodiment refer to electrodes that are led from the two excitation electrodes.

Moreover, a part of the two excitation electrodes (first excitation electrode and second excitation electrode) is formed within the grooves 63a and 63b. Thus, even when the tuning fork crystal resonator plate 2 is made smaller in size, vibration loss in the leg portions 61a and 61b is suppressed, and the CI value (crystal impedance) can be kept low. Of the two excitation electrodes, the first excitation electrode is composed of a first major surface electrode (not shown) formed in both major surfaces (front major surface and rear major surface) and the groove 63a of the first leg portion 61a, and a second side surface electrode (not shown) formed in both side surfaces of the second leg portion 61b. The first major surface electrode and the second side surface electrode are connected to each other by a routing electrode (not shown) and led to the lead electrode 65a (or the lead electrode 65b). Similarly, the second excitation electrode is composed of a second major surface electrode (not shown) formed in both major surfaces (front major surface and rear major surface) and the groove 63b of the second leg portion 61b, and a first side surface electrode (not shown) formed in both side surfaces of the first leg portion 61a. The second major surface electrode and the first side surface electrode are connected to each other by a routing electrode (not shown) and led to the lead electrode 65b (or the lead electrode 65a).

The above-described excitation electrodes are each a multilayer thin film composed of, for example, an underlying electrode layer of chromium and an upper electrode layer of gold. This thin film is formed on an entire surface by a method such as vacuum deposition, before being formed into a desired shape by performing metal etching using a photolithographic technique. Also, the above-described lead electrodes 65a and 65b shown in FIGS. 1 and 2 are each a multilayer thin film composed of, for example, an underlying electrode layer of chromium, an intermediate electrode layer of gold, and an upper electrode layer of chromium. This thin film is formed on an entire surface by a method such as vacuum deposition, before being formed into a desired shape by performing metal etching using a photolithographic technique, and only the upper electrode layer of chromium is formed using a method such as vacuum deposition while partially masking. Although the excitation electrodes are formed in the order of chromium and gold, the excitation electrodes may be formed in the order of chromium and silver, or in the order of chromium, gold, and chromium, or in the order of chromium, silver, and chromium, for example. Moreover, although the lead electrodes 65a and 65b are formed in the order of chromium, gold, and chromium, the lead electrodes 65a and 65b may be formed in the order of chromium, silver, and chromium, for example.

Regarding the base portion 62 of the tuning fork crystal resonator plate 2, as shown in FIG. 1, the base portion 62 is formed wider than the vibrating portion (leg portions 61a and 61b) and has a base portion central region 621 that has the same width as the vibrating portion and from which the vibrating portion (leg portions 61a and 61b) extends, and base portion wider regions 622 and 623 that extend beyond the edges of the vibrating portion in a width direction thereof. That is to say, as shown in FIG. 1, the base portion 62 is composed of the base portion wider regions 622 and 623 and the base portion central region 621 that are disposed adjacent to each other. As shown in FIG. 1, elongated thin-walled portions 7a and 7b designed with a narrow width and having a concave cross section are formed in both major surfaces (front major surface and rear major surface) of this base portion 62. These thin-walled portions 7a and 7b are formed to start at boundary corner portions 64a and 64b (serving as one end portions) that lie on boundaries 69 between the base portion central region 621 and the base portion wider regions 622 and 623 and that are located on a side of the base portion 62 from which the leg portions 61a and 61b extend. That is to say, the boundary corner portions 64a and 64b are used as starting end portions, which are one end portions of the thin-walled portions 7a and 7b. Moreover, the thin-walled portions 7a and 7b run from the base portion wider regions 622 and 623 over the base portion central region 621, and when the base portion 62 shown in FIG. 1 is viewed from the top, terminal end portions 71a and 71b (the other end portions) of the thin-walled portions 7a and 7b are located farther inside the base potion 62 than the conductive bonding member forming regions (lead electrodes 65a and 65b shown in FIG. 1). Thus, when the base portion 62 shown in FIG. 1 is viewed from the top, the lead electrodes 65a and 65b shown in FIG. 1 are formed on the outer side of the thin-walled portions 7a and 7b in the base potion 62. Thus, the thin-walled portions 7a and 7b are formed to inhibit linear connection of the conductive bonding member forming regions (lead electrodes 65a and 65b shown in FIG. 1) and the vibrating portion (leg portions 61a and 61b), as shown in FIG. 1. That is to say, the thin-walled portions 7a and 7b are interposed between the vibrating portion (leg portions 61a and 61b) and the conductive bonding material forming regions (lead electrodes 65a and 65b shown in FIG. 1). Moreover, the thin-walled portions 7a and 7b are formed in a desired shape by performing half-etching using a photolithographic technique, and in this embodiment, are formed in upper and lower surfaces (both major surfaces) of the base portion 62 in an opposed manner.

The lead electrodes 65a and 65b of the tuning fork crystal resonator plate 2 and the electrode pads 35 and 36 of the base 3 are bonded together via the conductive bonding member 5, and thus, the lead electrodes 65a and 65b and the electrode pads 35 and 36 are electrically connected to each other.

As described above, with the tuning fork crystal resonator plate 2 according to this embodiment, it is possible to effectively dispose the conductive bonding member forming regions (lead electrodes 65a and 65b shown in FIG. 1) in the base portion wider regions 622 and 623 without increasing the length of the base portion 62 of the tuning fork crystal resonator plate 2 while separating the two conductive bonding member forming regions in which the lead electrodes 65a and 65b shown in FIG. 1 for bonding to the electrode pads 35 and 36 of the base 3 are formed from each other, and also the bond strength of the tuning fork crystal resonator plate 2 to the base 3 is not decreased. In addition, the rigidity of the base portion 62 of the tuning fork crystal resonator plate 2 is not decreased, and leakage of vibration in the leg portions 61a and 61b to the conductive bonding member forming regions (lead electrodes 65a and 65b shown in FIG. 1) can be alleviated more efficiently.

That is to say, with the tuning fork crystal resonator plate 2 according to this embodiment, transmission of vibrational energy generated in the vibrating portion (leg portions 61a and 61b) is weakened by the base portion wider regions 622 and 623 and efficiently blocked by the thin-walled portions 7a and 7b starting at the boundary corner portions 64a and 64b between the base portion central region 621 and the base portion wider regions 622 and 623. Accordingly, it is possible to reduce leakage of vibration from the vibrating portion (leg portions 61a and 61b) to each of the conductive bonding member forming regions (lead electrodes 65a and 65b shown in FIG. 1) while realizing a reduction in the size of the base portion 62. Moreover, since the elongated thin-walled portions 7a and 7b starting at the boundary corner portions 64a and 64b between the base portion central region 621 and the base portion wider regions 622 and 623 are formed, it is possible to effectively dispose the conductive bonding member forming regions (lead electrodes 65a and 65b shown in FIG. 1) in the base portion wider regions 622 and 623 without increasing the length of the base portion 62 of the tuning fork crystal resonator plate 2, and also the bond strength of the tuning fork crystal resonator plate 2 is not decreased. In addition, since the thin-walled portions 7a and 7b are elongated, the rigidity of the base portion 62 of the tuning fork crystal resonator plate 2 is not decreased, and breakage or the like of the tuning fork crystal resonator plate 2 no longer occurs.

Next, a second embodiment of the present invention will be described with reference to FIG. 3. The present invention is applied to a tuning fork crystal resonator as a piezoelectric resonator device according to the second embodiment, as is the case with the first embodiment. Thus, in the second embodiment, a configuration different from that of the above-described first embodiment will be described, and the description of the same configuration will be omitted. Therefore, the functions and effects of the same configuration are similar to those of the above-described first embodiment.

The second embodiment is different from the above-described first embodiment in that a conductive bump such as a metal bump or a metal-plated bump is used as the material for the conductive bonding member 5. That is to say, for example, metal bumps 51 such as gold bumps are interposed between the lead electrodes 65a and 65b of the tuning fork crystal resonator plate 2 and the electrode pads 35 and 36 of the base 3, and the lead electrodes 65a and 65b and the electrode pads 35 and 36 are bonded to each other by applying ultrasonic waves to the tuning fork crystal resonator plate 2 from the above. In this case, the area of the conductive bonding member forming regions (lead electrodes 65a and 65b shown in FIG. 3) can be reduced as compared to the case of the conductive adhesive of the first embodiment, which can contribute to a further reduction in the size of the tuning fork crystal resonator plate 2. Moreover, in this embodiment, also an impact caused by applying ultrasonic waves during bonding of the gold bumps is absorbed by the thin-walled portions 7a and 7b, so that cracking or chipping of the tuning fork crystal resonator plate 2 can be avoided.

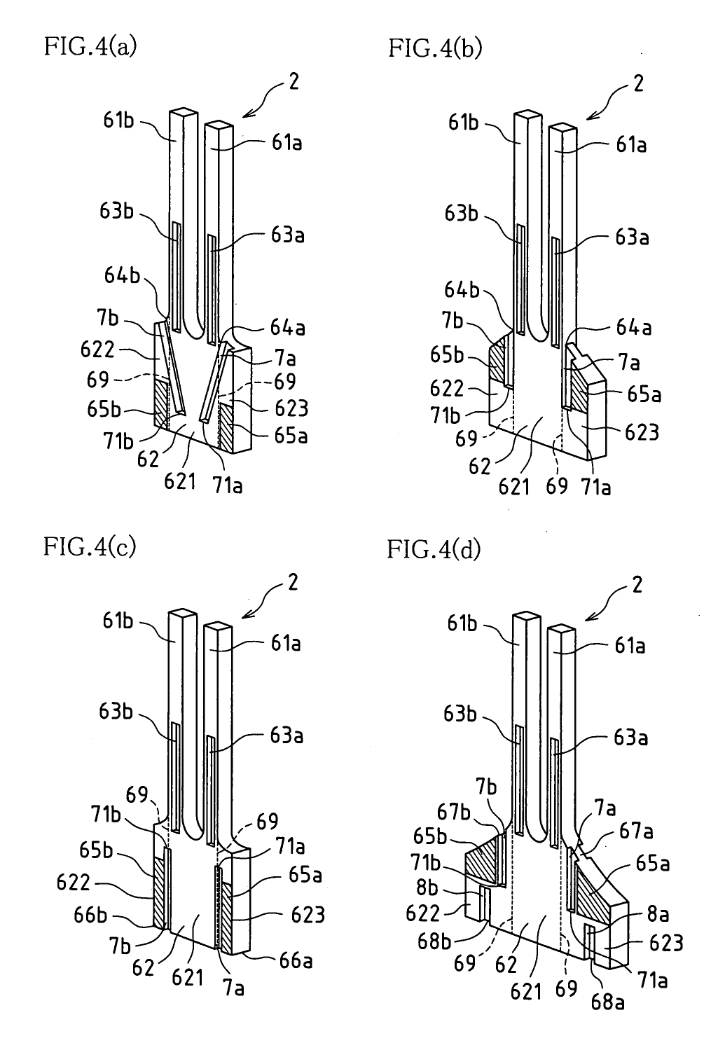

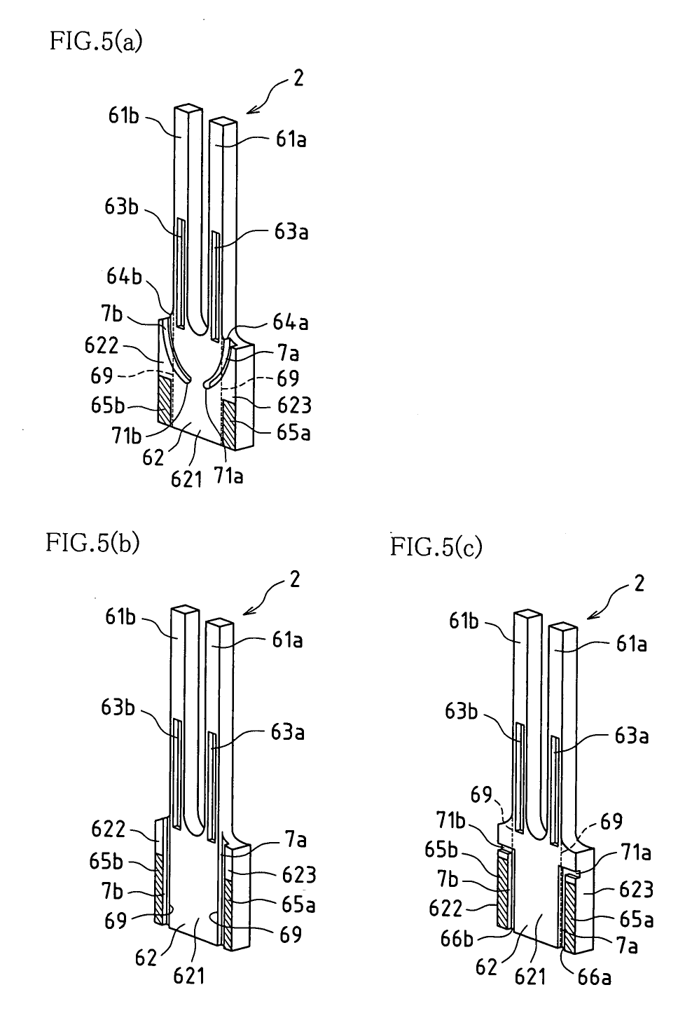

Next, with regard to the above-described embodiments of the present invention, variant examples of the configuration of the thin-walled portions 7a and 7b and the conductive bonding member forming regions (locations where the lead electrodes 65a and 65b shown in FIG. 1 are formed in the base portion 62) of the tuning fork crystal resonator plate 2 will be described with reference to FIG. 4 (FIGS. 4(a) to 4(d)) and FIG. 5 (FIGS. 5(a) to 5(c)). In the variant examples, a configuration different from that of the above-described embodiments will be described, and the description of the same configuration will be omitted. Therefore, the functions and effects of the same configuration are similar to those of the above-described first and second embodiments.

A tuning fork crystal resonator plate 2 in FIG. 4(a) is different from the above-described embodiments in that thin-walled portions 7a and 7b are formed by half-etching only a major surface at the front (front major surface) using a photolithographic technique. It should be noted that the surface to be half-etched may be on the side of a bonding portion or on another side.

In a tuning fork crystal resonator plate 2 in FIG. 4(b), thin-walled portions 7a and 7b are formed to start at the boundary corner portions 64a and 64b (serving as one end portions) that lie on the boundaries 69 between the base portion central region 621 and the base portion wider regions 622 and 623 and that are located on a side of the base portion 62 from which the leg portions 61a and 61b extend. These thin-walled portions 7a and 7b are formed along the boundaries 69, and when the base portion 62 shown in FIG. 4(b) is viewed from the top, the terminal end portions 71a and 71b (the other end portions) of the thin-walled portions 7a and 7b are located farther inside the base portion 62 than the lead electrodes 65a and 65b constituting the conductive bonding member forming regions. Moreover, when the base portion 62 shown in FIG. 4(b) is viewed from the top, the conductive bonding member forming regions (see the lead electrodes 65a and 65b shown in FIG. 4(b)) are disposed adjacent to (parallel to) the outer side of the thin-walled portions 7a and 7b in the base portion 62. Thus, even when the lead electrodes 65a and 65b formed in the conductive bonding member forming regions are disposed close to the vibrating portion (leg portions 61a and 61b), the influence of leakage of vibration is small, so that a further reduction in the size of the base portion can be realized by suppressing an increase in the length of the base portion.

A tuning fork crystal resonator plate 2 in FIG. 4(c) is different from the above-described embodiments in that thin-walled portions 7a and 7b are formed by half-etching only a major surface at the front (front major surface) using a photolithographic technique, as is the case with the thin-walled portions 7a and 7b shown in FIG. 4(a). It should be noted that the surface to be half-etched may be on the side of a bonding portion or on another side. Moreover, in the tuning fork crystal resonator plate 2 in FIG. 4(c), the thin-walled portions 7a and 7b are formed to start at boundary corner portions 66a and 66b (serving as one end portions) that lie on the boundaries 69 between the base portion central region 621 and the base portion wider regions 622 and 623 and that are located on the opposite side of a side of the base portion 62 from which the leg portions 61a and 61b extend. These thin-walled portions 7a and 7b are formed along the boundaries 69, and when the base portion 62 shown in FIG. 4(c) is viewed from the top, the terminal end portions 71a and 71b (the other end portions) of the thin-walled portions 7a and 7b are located farther inside the base portion 62 than the lead electrodes 65a and 65b constituting the conductive bonding member forming regions. Moreover, when the base portion 62 shown in FIG. 4(c) is viewed from the top, the conductive bonding member forming regions (see lead electrodes 65a and 65b shown in FIG. 4(c)) are disposed adjacent to (parallel to) the outer side of the thin-walled portions 7a and 7b in the base portion 62.

In a tuning fork crystal resonator plate 2 in FIG. 4(d), thin-walled portions 7a, 7b, 8a, and 8b are formed to start at corner portions 67a, 67b, 68a, and 68b (serving as one end portions) that are located on the outer side of boundary regions (boundaries 69) in the base portion 62 (in the base portion wider regions 622 and 623), rather than at the boundary corner portions 64a, 64b, 66a, and 66b between the base portion central region 621 and the base portion wider regions 622 and 623 as described above. Specifically, in the tuning fork crystal resonator plate 2 in FIG. 4(d), the thin-walled portions 7a and 7b are formed to start at the corner portions 67a and 67b (serving as one end portions) that lie in the base portion wider regions 622 and 623 and that are located on a side of the base portion 62 from which the leg portions 61a and 61b extend. These thin-walled portions 7a and 7b are formed along the boundaries 69, and when the base portion 62 shown in FIG. 4(d) is viewed from the top, the terminal end portions 71a and 71b (the other end portions) of the thin-walled portions 7a and 7b are located farther inside the base portion 62 than the lead electrodes 65a and 65b constituting the conductive bonding member forming regions. Also, the thin-walled portions 8a and 8b are formed to start at the corner portions 68a and 68b (serving as one end portions) that lie in the base portion wider regions 622 and 623 and that are located on the opposite side of the side of the base portion 62 from which the leg portions 61a and 61b extend. These thin-walled portions 8a and 8b are formed along the boundaries 69. Thus, the conductive bonding member forming regions (lead electrodes 65a and 65b shown in FIG. 4(d)) can be disposed close to the vibrating portion (leg portions 61a and 61b), so that a further reduction in the size of the base portion 62 can be realized by suppressing an increase in the length of the base portion 62. Furthermore, the thin-walled portions 7a, 7b, 8a, and 8b are disposed opposed in the corner portions 67a, 67b, 68a, and 68b in the base portion 62. Thus, leakage of vibration in the leg portions 61a and 61b to the base portion 62 can be alleviated more efficiently without increasing the length of the base portion 62 of the tuning fork crystal resonator plate 2. In particular, transmission of the vibrational energy generated in the vibrating portion (leg portions 61a and 61b) is weakened by the base portion wider regions 622 and 623 and efficiently blocked at a position closest to the vibrating portion (leg portions 61a and 61b) by the thin-walled portions 7a and 7b starting at the corner portions on the side of the base portion wider regions 622 and 623 from which the leg portions extend. Accordingly, it is possible to suppress diffusion of leakage of vibration to the base portion 62 and reduce the leakage of vibration from the vibrating portion (leg portions 61a and 61b) to each of the conductive bonding member forming regions (lead electrodes 65a and 65b shown in FIG. 4(d)) while realizing a reduction in the size of the base portion 62.

A tuning fork crystal resonator plate 2 in FIG. 5(a) is different from the above-described embodiments in that thin-walled portions 7a and 7b are formed by half-etching only a major surface at the front (front major surface) using a photolithographic technique, as is the case with the thin-walled portions 7a and 7b shown in FIG. 4(a). It should be noted that the surface to be half-etched may be on the side of a bonding portion or on another side. Moreover, the thin-walled portions 7a and 7b shown in FIG. 5(a) are formed to start at the boundary corner portions 64a and 64b (serving as one end portions) that lie on the boundaries 69 between the base portion central region 621 and the base portion wider regions 622 and 623 and that are located on a side of the base portion 62 from which the leg portions 61a and 61b extend. Furthermore, when the base portion 62 shown in FIG. 5(a) is viewed from the top, the thin-walled portions 7a and 7b run from the base portion wider regions 622 and 623 over the base portion central region 621 while curving toward the opposite side of the side of the base portion 62 from which the leg portions 61a and 61b extend. That is to say, when the base portion 62 shown in FIG. 5(a) is viewed from the top, the thin-walled portions 7a and 7b are curved such that the thin-walled portions 7a and 7b bulge downward in the drawing. The terminal end portions 71a and 71b (the other end portions) of the thin-walled portions 7a and 7b are located farther inside the base portion 62 than the conductive bonding member forming regions (lead electrodes 65a and 65b shown in FIG. 5(a)). That is to say, the lead electrodes 65a and 65b shown in FIG. 5(a) are formed on the outer side of the thin-walled portions 7a and 7b in the base portion 62 shown in FIG. 5(a). Moreover, the shape of the thin-walled portions 7a and 7b is not limited to the shape of the thin-walled portions 7a and 7b that are curved as shown in FIG. 5(a), and it is also possible that the thin-walled portions 7a and 7b are formed in a stepwise manner from the one end portions (boundary corner portions 64a and 64b) to the terminal end portions 71a and 71b (the other end portions) and the lead electrodes 65a and 65b are formed on the outer side of the thin-walled portions 7a and 7b in the base portion 62.

A tuning fork crystal resonator plate 2 in FIG. 5(b) is different from the above-described embodiments in that thin-walled portions 7a and 7b are formed by half-etching only a major surface at the front (front major surface) using a photolithographic technique, as is the case with the thin-walled portions 7a and 7b shown in FIG. 4(a). It should be noted that the surface to be half-etched may be on the side of a bonding portion or on another side. However, it is preferable that the surface to be half-etched is the front major surface of the base portion 62 in order to achieve good electrical conduction to the excitation electrodes that are not shown so that the excitation electrodes are electrically connected to the electrode pads 35 and 36. In the tuning fork crystal resonator plate 2 in FIG. 5(b), the thin-walled portions 7a and 7b are formed along and substantially on the boundaries 69 between the base portion central region 621 and the base portion wider regions 622 and 623, and run from a side of the base portion 62 from which the leg portions 61a and 61b extend to the opposite side. Therefore, when the base portion 62 shown in FIG. 5(b) is viewed from the top, the thin-walled portions 7a and 7b are disposed farther inside the base portion 62 than the lead electrodes 65a and 65b constituting the conductive bonding member forming regions.

A tuning fork crystal resonator plate 2 in FIG. 5(c) is different from the above-described embodiments in that thin-walled portions 7a and 7b are formed by half-etching only a major surface at the front (front major surface) using a photolithographic technique, as is the case with the thin-walled portions 7a and 7b shown in FIG. 4(a). It should be noted that the surface to be half-etched may be on the side of a bonding portion or on another side. However, it is preferable that the surface to be half-etched is the front major surface of the base portion 62 in order to achieve good electrical conduction to the excitation electrodes that are not shown so that the excitation electrodes are electrically connected to the electrode pads 35 and 36. Moreover, in the tuning fork crystal resonator plate 2 in FIG. 5(c), the thin-walled portions 7a and 7b are formed to start at boundary corner portions 66a and 66b (serving as one end portions) that lie on the boundaries 69 between the base portion central region 621 and the base portion wider regions 622 and 623 and that are located on the opposite side of a side of the base portion 62 from which the leg portions 61a and 61b extend. The thin-walled portions 7a and 7b are formed along the boundaries 69, and are bent in a width direction of the base portion 62 to reach side surfaces of the base portion wider regions 622 and 623, which serve as the terminal end portions 71a and 71b (the other end portions) of the thin-walled portions 7a and 7b, so as to surround the lead electrodes 65a and 65b shown in FIG. 5(c).

The present invention can be embodied and practiced in other different forms without departing from the spirit and essential characteristics thereof. For example, although the case where the terminal end portions of the thin-walled portions are located farther inside the base portion than the conductive bonding member forming regions is disclosed in the above-described embodiments, this case is a preferred example, and the present invention is not limited to this. Moreover, although the case where the thin-walled portions inhibit linear connection of the conductive bonding member forming regions and the vibrating portion is disclosed, this case is a preferred example, and the present invention is not limited to this. Furthermore, although the thin-walled portions have their terminal end portions in the midst of the base portion, the thin-walled portions may run all the way across the base portion. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

This application claims priority on Patent Application No. 2005-190822 filed in Japan on Jun. 30, 2005, the entire contents of which are hereby incorporated by reference.

### INDUSTRIAL APPLICABILITY

As the material for the piezoelectric resonator plate according to the present invention, crystal crystal is preferably used.

1. A piezoelectric resonator plate, comprising a base portion and a vibrating portion having a plurality of leg portions protruding from the base portion,
wherein each of the leg portions is provided with an excitation electrode having a different potential and a lead electrode connected to the excitation electrode so as to electrically connect the excitation electrode to an external electrode,
at least two conductive bonding member forming regions for bonding a part of the lead electrode to the external electrode via a conductive bonding member are defined in the base portion,
the base portion is formed wider than the vibrating portion and has a base portion central region and base portion wider regions, the base portion central region having the same width as the vibrating portion, the vibrating portion extending from the base portion central region, and the base portion wider regions extending beyond lateral edges of the vibrating portion, the conductive bonding member forming regions being defined in the base portion wider regions, and
elongated thin-walled portions starting at boundary corner portions of the base portion between the base portion central region and the base portion wider regions are formed in the base portion.

2. A piezoelectric resonator plate, comprising a base portion and a vibrating portion having a plurality of leg portions protruding from the base portion,
wherein each of the leg portions is provided with an excitation electrode having a different potential and a lead electrode connected to the excitation electrode so as to electrically connect the excitation electrode to an external electrode,
at least two conductive bonding member forming regions for bonding a part of the lead electrode to the external electrode via a conductive bonding member are defined in the base portion,
the base portion is formed wider than the vibrating portion and has a base portion central region and base portion wider regions, the base portion central region having the same width as the vibrating portion, the vibrating portion extending from the base portion central region, and the base portion wider regions extending beyond lateral edges of the vibrating portion, the conductive bonding member forming regions being defined in the base portion wider regions, and
elongated thin-walled portions starting at corner portions on a side of the base portion wider regions from which the leg portions extend are formed in the base portion.

3. The piezoelectric resonator plate according to claim 1,
wherein terminal end portions of the thin-walled portions are located farther inside the base portion than the conductive bonding member forming regions.

4. The piezoelectric resonator plate according to claim 1,
wherein the conductive bonding member comprises a conductive adhesive.

5. The piezoelectric resonator plate according to claim 1,
wherein the conductive bonding member comprises a conductive bump.

6. The piezoelectric resonator plate according to claim 1,
wherein the leg portion has a groove in a major surface thereof, and a part of the excitation electrode is formed within the groove.

7. A piezoelectric resonator device,
wherein a base and a lid are bonded together to form a housing inside of which is hermetically enclosed,
the base within the housing is provided with an electrode pad constituting the external electrode, and
the conductive bonding member forming region of the piezoelectric resonator plate according to claim 1 is bonded to the electrode pad via a conductive bonding member.

8. The piezoelectric resonator plate according to claim 2,
wherein terminal end portions of the thin-walled portions are located farther inside the base portion than the conductive bonding member forming regions.

9. The piezoelectric resonator plate according to claim 2,
wherein the conductive bonding member comprises a conductive adhesive.

10. The piezoelectric resonator plate according to claim 3,
wherein the conductive bonding member comprises a conductive adhesive.

11. The piezoelectric resonator plate according to claim 2,
wherein the conductive bonding member comprises a conductive bump.

12. The piezoelectric resonator plate according to claim 3,
wherein the conductive bonding member comprises a conductive bump.

13. The piezoelectric resonator plate according to claim 2,
wherein the leg portion has a groove in a major surface thereof, and a part of the excitation electrode is formed within the groove.

14. The piezoelectric resonator plate according to claim 3,
wherein the leg portion has a groove in a major surface thereof, and a part of the excitation electrode is formed within the groove.

15. The piezoelectric resonator plate according to claim 4,
wherein the leg portion has a groove in a major surface thereof, and a part of the excitation electrode is formed within the groove.

16. The piezoelectric resonator plate according to claim 5,
wherein the leg portion has a groove in a major surface thereof, and a part of the excitation electrode is formed within the groove.

17. A piezoelectric resonator device,
wherein a base and a lid are bonded together to form a housing inside of which is hermetically enclosed,
the base within the housing is provided with an electrode pad constituting the external electrode, and
the conductive bonding member forming region of the piezoelectric resonator plate according to claim 2 is bonded to the electrode pad via a conductive bonding member.

18. A piezoelectric resonator device,
wherein a base and a lid are bonded together to form a housing inside of which is hermetically enclosed,
the base within the housing is provided with an electrode pad constituting the external electrode, and
the conductive bonding member forming region of the piezoelectric resonator plate according to claim 3 is bonded to the electrode pad via a conductive bonding member.

19. A piezoelectric resonator device,
wherein a base and a lid are bonded together to form a housing inside of which is hermetically enclosed,
the base within the housing is provided with an electrode pad constituting the external electrode, and
the conductive bonding member forming region of the piezoelectric resonator plate according to claim 4 is bonded to the electrode pad via a conductive bonding member.

20. A piezoelectric resonator device,
wherein a base and a lid are bonded together to form a housing inside of which is hermetically enclosed,
the base within the housing is provided with an electrode pad constituting the external electrode, and
the conductive bonding member forming region of the piezoelectric resonator plate according to claim 5 is bonded to the electrode pad via a conductive bonding member.
